(19) United States
(12) Patent Application Publication
(10) Pub. No.: US 2026/0020457 A1
(43) Pub. Date: Jan. 15, 2026

(54) DISPLAY DEVICE AND MOBILE ELECTRONIC DEVICE INCLUDING SAME

(71) Applicant: Samsung Display Co., Ltd., Yongin-si (KR)

(72) Inventor: Han Ho PARK, Yongin-si (KR)

(21) Appl. No.: 19/199,233

(22) Filed: May 5, 2025

(30) Foreign Application Priority Data
Jul. 11, 2024 (KR) 10-2024-0091505

(51) Int. Cl. H10K 59/131; H10K 59/95

(52) U.S. Cl. CPC H10K 59/131; H10K 59/95

(57) ABSTRACT

A display device includes: a display panel on which a display element layer comprising a light-emitting element is located; an integrated circuit (IC) bonded to a first pad portion of the display panel, and comprising a non-overlapping region that does not overlap the display panel; a circuit board bonded to the non-overlapping region of the integrated circuit; and a molding member covering the integrated circuit and a portion of the display panel to which the integrated circuit is bonded.

### CROSS-REFERENCE TO RELATED APPLICATION

The present application claims priority to and the benefit of Korean Patent Application No. 10-2024-0091505 filed on Jul. 11, 2024, in the Korean Intellectual Property Office, the entire disclosure of which is incorporated herein by reference.

### BACKGROUND

### 1. Field

Aspects of some embodiments of the present disclosure relate to a display device and a mobile electronic device including the same.

### 2. Description of the Related Art

With the advance of information-oriented society, more and more demands are placed on display devices for displaying images in various ways. Display devices may be flat panel display devices such as liquid crystal displays, field emission displays and light-emitting displays. A light-emitting display device may include an organic light-emitting display device including an organic light-emitting diode element as a light-emitting element or a light-emitting diode display device including an inorganic light-emitting diode element such as a light-emitting diode (LED) as a light-emitting element.

The display device includes a display area in which pixels displaying images are displayed, and a non-display area (or bezel area) arranged around (e.g., in a periphery or outside a footprint of) the display area and in which lines for driving the pixels are located. A bezel-less display device may increase or maximize the area of the display area. There is an increasing demand for a display device in which the area of the non-display area is reduced by forming a line on a side surface of a substrate.

The display device may include driving circuits such as a timing controller and a power circuit for driving pixels included in a display panel. The driving circuits, such as the timing controller and the power circuit, generate more heat than other components of the display device, and the heat generated by the driving circuit may relatively reduce the lifespan of the organic light-emitting layer of the pixel.

The above information disclosed in this Background section is only for enhancement of understanding of the background and therefore the information discussed in this Background section does not necessarily constitute prior art.

### SUMMARY

Aspects of some embodiments of the present disclosure include a display device capable of reducing the area of a non-display area and preventing or reducing damage to an organic light-emitting layer from heat generated by a driving circuit of the display device, and a mobile electronic device including the same.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes, a display panel on which a display element layer including a light-emitting element is located, an integrated circuit (IC) bonded to a first pad portion of the display panel, and including a non-overlapping region that does not overlap the display panel, a circuit board bonded to the non-overlapping region of the integrated circuit, and a molding member covering the integrated circuit and a portion of the display panel to which the integrated circuit is bonded.

According to some embodiments, the integrated circuit comprises, a plurality of first bumps bonded to the first pad portion of the display panel, and a plurality of second bumps bonded to a second pad portion of the circuit board.

According to some embodiments, the integrated circuit comprises a timing controller and a power supply circuit for driving the display panel.

According to some embodiments, the timing controller and the power supply circuit are inside the integrated circuit, and are adjacent to the plurality of second bumps.

According to some embodiments, the molding member contains a material having heat dissipation characteristics.

According to some embodiments, the circuit board is a flexible printed circuit board extending in an outward direction of the display panel, as the second pad portion is aligned in a forward direction with the plurality of second bumps of the integrated circuit.

According to some embodiments, the circuit board is a flexible printed circuit board extending in an inward direction of the display panel, as the second pad portion is aligned in a reverse direction with the plurality of second bumps of the integrated circuit.

According to some embodiments, the circuit board is a chip on film (COF).

According to some embodiments, the first pad portion of the display panel comprises a first alignment mark for identifying a boundary of a corner of the integrated circuit, and the first alignment mark has a bent shape that does not overlap the integrated circuit.

According to some embodiments, the integrated circuit comprises a second alignment mark for identifying a boundary of the non-overlapping region, and the second alignment mark has a bent shape at the boundary of the non-overlapping region.

According to some embodiments, the integrated circuit comprises at least one step compensation bump between the plurality of first bumps and the plurality of second bumps.

According to some embodiments, the display panel is an organic light-emitting diode-on-silicon (OLEDoS) in which the light-emitting element is on a silicon substrate.

According to some embodiments of the present disclosure, a mobile electronic device includes, a display panel on which a display element layer including a light-emitting element is located, an integrated circuit (IC) bonded to a first pad portion located on a side surface of the display panel, and including a non-overlapping region that does not overlap the display panel, a circuit board bonded to the non-overlapping region of the integrated circuit, and a molding member covering the integrated circuit and a portion of the display panel to which the integrated circuit is bonded.

According to some embodiments, the integrated circuit comprises, a plurality of first bumps bonded to the first pad portion of the display panel, and a plurality of second bumps bonded to a second pad portion of the circuit board.

According to some embodiments, the integrated circuit comprises a timing controller and a power supply circuit for driving the display panel.

According to some embodiments, the timing controller and the power supply circuit are inside the integrated circuit, and are adjacent to the plurality of second bumps.

According to some embodiments, the molding member contains a material having heat dissipation characteristics.

According to some embodiments, the circuit board is a flexible printed circuit board extending in an outward direction of the display panel, as the second pad portion is aligned in a forward direction with the plurality of second bumps of the integrated circuit.

According to some embodiments, the first pad portion of the display panel comprises a first alignment mark for identifying a boundary of a corner of the integrated circuit, and the first alignment mark has a bent shape that does not overlap the integrated circuit.

According to some embodiments, the integrated circuit comprises a second alignment mark for identifying a boundary of the non-overlapping region, and the second alignment mark has a bent shape at the boundary of the non-overlapping region.

In the display device and the mobile electronic device including the same according to some embodiments, the area of the non-display area may be relatively reduced, and damage to the organic light-emitting layer from heat generated by the driving circuit of the display device may be prevented or reduced.

However, the characteristics of embodiments according to the present disclosure are not limited to those described above and various other characteristics are incorporated herein.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is an exploded perspective view showing a display device according to some embodiments;

FIG. 2 is a block diagram illustrating a display device according to some embodiments;

FIG. 3 is an equivalent circuit diagram of a first sub-pixel according to some embodiments;

FIG. 4 is a layout diagram illustrating an example of a display panel according to some embodiments;

FIGS. 5 and 6 are layout diagrams illustrating further details of the display area of FIG. 4;

FIG. 7 is a cross-sectional view illustrating further details of a display panel taken along the line I1-I1′ of FIG. 5

FIG. 8 is a perspective view illustrating a head mounted display according to some embodiments;

FIG. 9 is an exploded perspective view illustrating an example of the head mounted display of FIG. 8;

FIG. 10 is a perspective view illustrating a head mounted display according to some embodiments;

FIG. 11 is a cross-sectional view schematically illustrating an integrated circuit bonded to a pad portion of a display panel according to some embodiments;

FIG. 12 is a configuration diagram of the integrated circuit shown in FIG. 11;

FIG. 13 is a cross-sectional view schematically illustrating a flexible printed circuit board bonded to the integrated circuit in a reverse direction according to some embodiments;

FIGS. 14 to 16 are conceptual diagrams illustrating a bonding process of the display device according to some embodiments;

FIGS. 17 to 19 are conceptual diagrams for describing a method of manufacturing the display device according to some embodiments;

FIGS. 20 and 21 are diagrams illustrating a first alignment mark of the display panel and a second alignment mark of the integrated circuit according to some embodiments;

FIG. 22 is a cross-sectional view illustrating the integrated circuit bonded to the side surface of the display panel according to some embodiments; and

FIGS. 23 and 24 are cross-sectional views illustrating an example in which the circuit board is a chip on film (COF) according to some embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

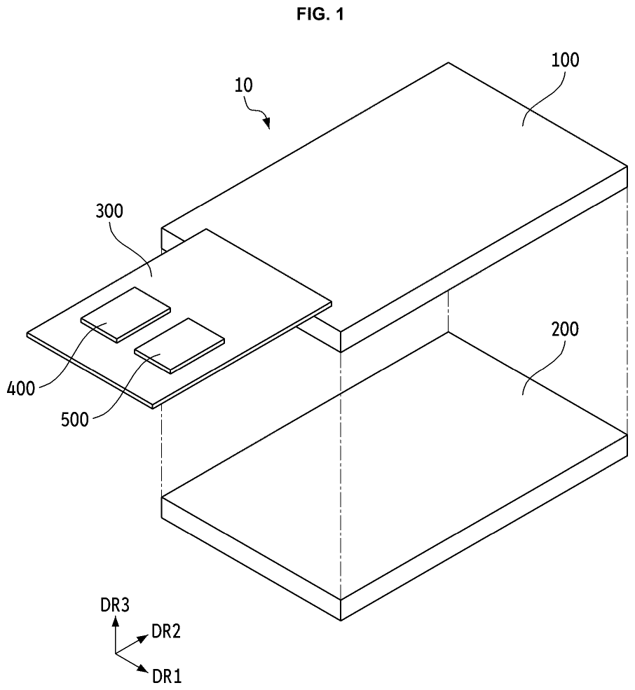

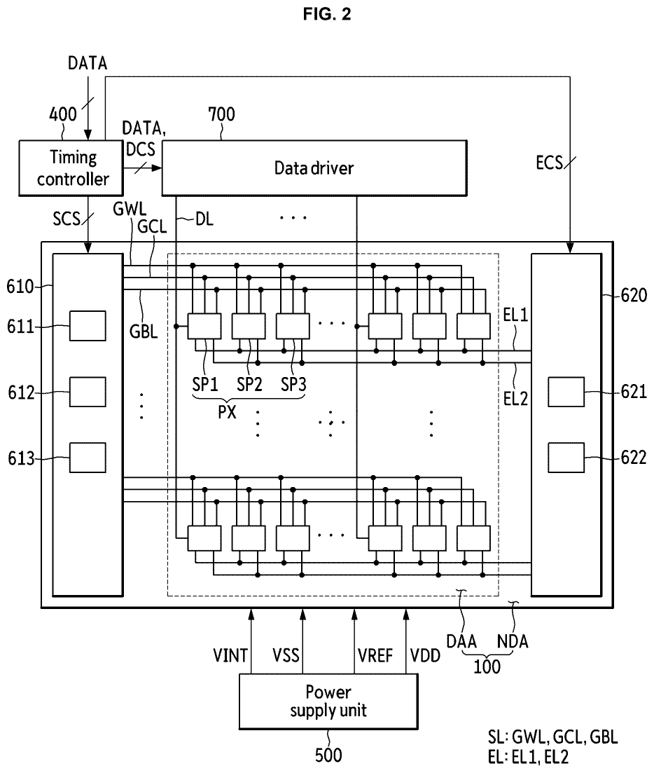

FIG. 1 is an exploded perspective view showing a display device according to some embodiments. FIG. 2 is a block diagram illustrating a display device according to some embodiments.

Referring to FIGS. 1 and 2, a display device 10 according to some embodiments is a device configured to display moving images (e.g., video images) or still images (e.g., static images). The display device 10 according to some embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to some embodiments may be applied as a display unit of a television, a laptop, a monitor, a billboard, or an Internet-of-Things (IoT) terminal. Alternatively, the display device 10 according to some embodiments may be applied to a smart watch, a watch phone, a head mounted display (HMD) for implementing virtual reality and augmented reality, and the like.

The display device 10 according to some embodiments includes a display panel 100, a heat dissipation layer 200, a circuit board 300, a timing controller 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a curvature (e.g., a set or predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but embodiments according to the present disclosure are not limited thereto.

The display panel 100 includes a display area DAA displaying images and a non-display area NDA not displaying images as shown in FIG. 2. According to some embodiments, the non-display area NDA may surround (e.g., in a periphery or outside a footprint of) the display area DAA.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

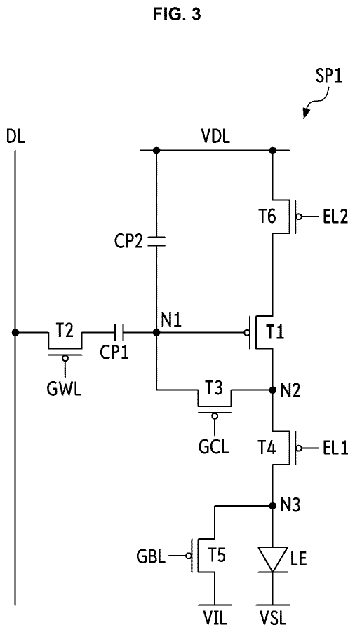

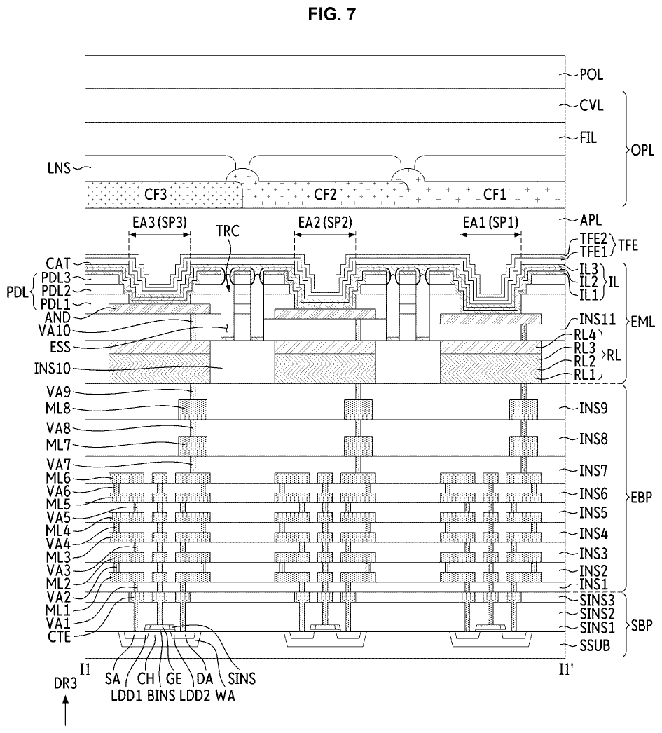

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and located on a semiconductor substrate SSUB (see FIG. 7). For example, the plurality of pixel transistors of a data driver 700 may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The non-display area NDA includes a scan driver 610, an emission driver 620, and the data driver 700.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS. Although it is illustrated in FIG. 2 that the scan driver 610 is located on the left side of the display area DAA and the emission driver 620 is located on the right side of the display area DAA, embodiments according to the present disclosure are not limited thereto. For example, the scan driver 610 and the emission driver 620 may be located on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

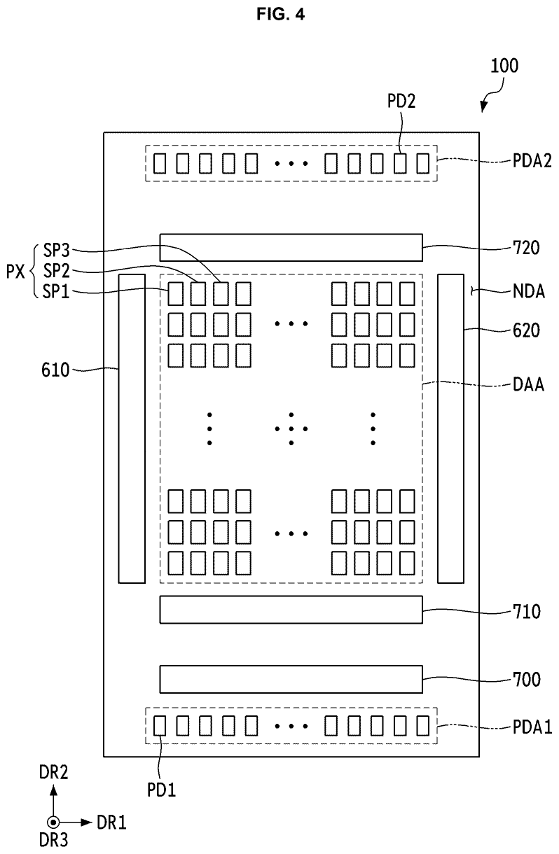

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing controller 400 may receive digital video data DATA and timing signals inputted from the outside. The timing controller 400 may generate the scan timing control signal SCS, the emission timing control signal ECS, and the data timing control signal DCS for controlling the display panel 100 in response to the timing signals. The timing controller 400 may output the scan timing control signal SCS to the scan driver 610, and output the emission timing control signal ECS to the emission driver 620. The timing controller 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing controller 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, similarly to the scan driver 610, the emission driver 620, and the data driver 700, each of the timing controller 400 and the power supply circuit 500 may be located in the non-display area NDA of the display panel 100. In this case, the timing controller 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing controller 400 and the power supply circuit 500 may be located between the data driver 700 and the first pad portion PDA1 (see FIG. 4).

FIG. 3 is an equivalent circuit diagram of a first sub-pixel according to some embodiments. Although FIG. 3 illustrates various components in a sub-pixel according to some embodiments, embodiments according to the present disclosure are not limited thereto, and according to various embodiments, the sub-pixel may include additional components or fewer components without departing from the spirit and scope of embodiments according to the present disclosure.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE emits light in response to a driving current flowing through the channel of a first transistor T1. The emission amount of the light-emitting element LE may be proportional to the driving current. The light-emitting element LE may be located between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but embodiments according to the present disclosure are not limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current (the driving current) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be located between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments according to the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be the same (or substantially the same) as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to some embodiments.

Referring to FIG. 4, the display area DAA of the display panel 100 according to some embodiments includes the plurality of pixels PX arranged in a matrix form. The non-display area NDA of the display panel 100 according to some embodiments includes the scan driver 610, the emission driver 620, the data driver 700, a first distribution circuit 710, a second distribution circuit 720, the first pad portion PDA1, and a second pad portion PDA2.

The scan driver 610 may be located on the first side of the display area DAA, and the emission driver 620 may be located on the second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, embodiments according to the present disclosure are not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on the third side of the display area DAA. For example, the first pad portion PDA1 may be located on one side of the display area DAA in the second direction DR2.

The first pad portion PDA1 may be located outside the data driver 700 in the second direction DR2. That is, the first pad portion PDA1 may be located closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection.

The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on the upper side of the display area DAA.

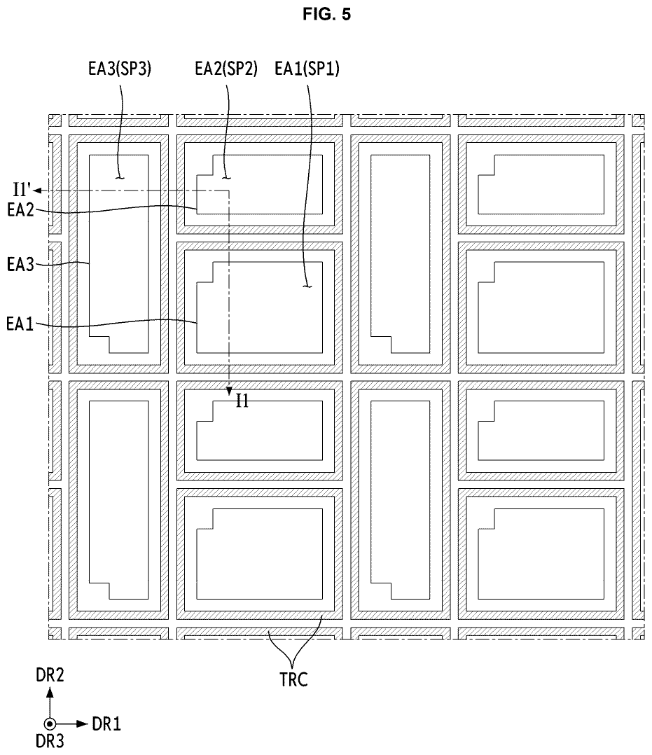

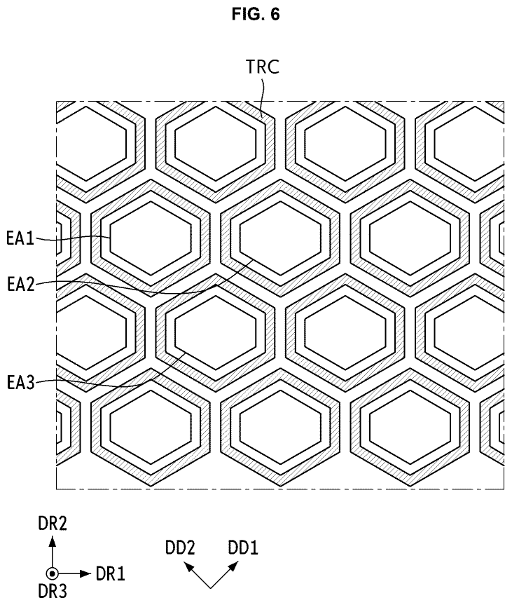

FIGS. 5 and 6 are layout diagrams illustrating embodiments of the display area of FIG. 4.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in plan view.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be the same (or substantially the same).

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in plan view, a hexagonal shape formed of six straight lines as shown in FIG. 6, but embodiments according to the present disclosure are not limited thereto. The first emission area EA1, the second emission area EA2, and the third emission area EA3 may have a polygonal shape other than a hexagon, a circular shape, an elliptical shape, or an atypical shape in plan view.

As shown in FIG. 5, in each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. In addition, the second emission area EA2 and the third emission area EA3 may be adjacent to each other in the first direction DR1. The area of the first emission area EA1, the area of the second emission area EA2, and the area of the third emission area EA3 may be different.

Alternatively, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of 370 nm to 460 nm (or about 370 nm to about 460 nm), the green wavelength band may be a wavelength band of light whose main peak wavelength is in the range of 480 nm to 560 nm (or about 480 nm to about 560 nm), and the red wavelength band may be a wavelength band of light whose main peak wavelength is in the range of 600 nm to 750 nm (or about 600 nm to about 750 nm).

It is illustrated in FIGS. 5 and 6 that each of the plurality of pixels PX includes three emission areas EA1, EA2, and EA3, but embodiments according to the present disclosure are not limited thereto. That is, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be arranged in a stripe structure in which the emission areas are arranged in the first direction DR1, a PenTile® structure in which the emission areas are arranged in a diamond shape, or a hexagonal structure in which the emission areas having, in plan view, a hexagonal shape are arranged as shown in FIG. 6.

FIG. 7 is a cross-sectional view illustrating an example of a display panel taken along the line I1-I1′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be located on the semiconductor substrate SSUB. The first semiconductor insulating film SINS1 may be formed of silicon carbonitride (SiCN) or a silicon oxide (SiOx)-based inorganic film, but embodiments according to the present disclosure are not limited thereto.

A second semiconductor insulating film SINS2 may be located on the first semiconductor insulating film SINS1. The second semiconductor insulating film SINS2 may be formed of a silicon oxide (SiOx)-based inorganic film, but embodiments according to the present disclosure are not limited thereto.

The plurality of contact terminals CTE may be located on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but embodiments according to the present disclosure are not limited thereto.

The semiconductor substrate SSUB may be replaced with a glass substrate or a polymer resin substrate such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS1 to INS9 located between the first to eighth conductive layers ML1 to ML8.

The first to eighth conductive layers ML1 to ML8 serve to connect the plurality of contact terminals CTE exposed from the semiconductor backplane SBP to thereby implement the circuit of the first sub-pixel SP1 shown in FIG. 3. For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be located on the semiconductor backplane SBP. Each of the first vias VA1 may penetrate the first insulating film INS1 and be connected to the contact terminal CTE exposed from the semiconductor backplane SBP. Each of the first conductive layers ML1 may be located on the first insulating film INS1 and may be connected to the first via VA1.

The second insulating film INS2 may be located on the first insulating film INS1 and the first conductive layers ML1. Each of the second vias VA2 may penetrate the second insulating film INS2 and be connected to the exposed first conductive layer ML1. Each of the second conductive layers ML2 may be located on the second insulating film INS2 and may be connected to the second via VA2.

The third insulating film INS3 may be located on the second insulating film INS2 and the second conductive layers ML2. Each of the third vias VA3 may penetrate the third insulating film INS3 and be connected to the exposed second conductive layer ML2. Each of the third conductive layers ML3 may be located on the third insulating film INS3 and may be connected to the third via VA3.

A fourth insulating film INS4 may be located on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be located on the fourth insulating film INS4 and may be connected to the fourth via VA4.

A fifth insulating film INS5 may be located on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be located on the fifth insulating film INS5 and may be connected to the fifth via VA5.

A sixth insulating film INS6 may be located on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be located on the sixth insulating film INS6 and may be connected to the sixth via VA6.

A seventh insulating film INS7 may be located on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be located on the seventh insulating film INS7 and may be connected to the seventh via VA7.

An eighth insulating film INS8 may be located on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be located on the eighth insulating film INS8 and may be connected to the eighth via VA8.

The first to eighth conductive layers ML1 to ML8 and the first to eighth vias VA1 to VA8 may be formed of the same (or substantially the same) material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of the same (or substantially the same) material. First to eighth insulating films INS1 to INS8 may be formed of a silicon oxide (SiOx)-based inorganic film, but embodiments according to the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be the same (or substantially the same). For example, the thickness of the first conductive layer ML1 may be 1360 Å (or approximately 1360 Å). The thickness of each of the second conductive layer ML2, the third conductive layer ML3, the fourth conductive layer ML4, the fifth conductive layer ML5, and the sixth conductive layer ML6 may be 1440 Å (or approximately 1440 Å). The thickness of each of the first via VA1, the second via VA2, the third via VA3, the fourth via VA4, the fifth via VA5, and the sixth via VA6 may be 1150 Å (or approximately 1150 Å).

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be the same (or substantially the same). For example, the thickness of each of the seventh conductive layer ML7 and the eighth conductive layer ML8 may be 9000 Å (or approximately 9000 Å). The thickness of each of the seventh via VA7 and the eighth via VA8 may be 6000 Å (or approximately 6000 Å).

A ninth insulating film INS9 may be located on the eighth insulating film INS8 and the eighth conductive layer ML8. The ninth insulating film INS9 may be formed of a silicon oxide (SiOx)-based inorganic film, but embodiments according to the present disclosure are not limited thereto.

Each of the ninth vias VA9 may penetrate the ninth insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be 16500 Å (or approximately 16500 Å).

The display element layer EML may be located on the light-emitting element backplane EBP. The display element layer EML may include light-emitting elements LE each including a reflective electrode layer RL, tenth and eleventh insulating films INS10 and INS11, a tenth via VA10, a first electrode AND, a light-emitting stack IL, and a second electrode CAT; a pixel defining film PDL; and a plurality of trenches TRC.

The reflective electrode layer RL may be located on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be located on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be located on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be located on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be located on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Because the second reflective electrode RL2 is an electrode that reflects (or substantially reflects) light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be 100 Å (or approximately 100 Å), and the thickness of the second reflective electrode RL2 may be 850 Å (or approximately 850 Å).

The tenth insulating film INS10 may be located on the ninth insulating film INS9. The tenth insulating film INS10 may be located between the reflective electrode layers RL adjacent to each other in a horizontal direction. The tenth insulating film INS10 may be formed of a silicon oxide (SiOx)-based inorganic film, but embodiments according to the present disclosure are not limited thereto.

The eleventh insulating film INS11 may be located on the tenth insulating film INS10 and the reflective electrode layer RL. The eleventh insulating film INS11 may be formed of a silicon oxide (SiOx)-based inorganic film, but embodiments according to the present disclosure are not limited thereto. The tenth insulating film INS10 and the eleventh insulating film INS11 may be an optical auxiliary layer through which light reflected by the reflective electrode layer RL passes, among light emitted from the light-emitting elements LE.

In order to match the resonance distance of the light emitted from the light-emitting elements LE in at least one of the first sub-pixel SP1, the second sub-pixel SP2, or the third sub-pixel SP3, the tenth insulating film INS10 or the eleventh insulating film INS11 may not be located under the first electrode AND. For example, the first electrode AND of the first sub-pixel SP1 may be directly located on the reflective electrode layer RL. The eleventh insulating film INS11 may be located under the first electrode AND of the second sub-pixel SP2. The tenth insulating film INS10 and the eleventh insulating film INS11 may be located under the first electrode AND of the third sub-pixel SP3.

In summary, the distance between the first electrode AND and the reflective electrode layer RL may be different in the first sub-pixel SP1, the second sub-pixel SP2, and the third sub-pixel SP3. That is, in order to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating film INS10 and the eleventh insulating film INS11 may be set in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. Embodiments according to the present disclosure are not limited to the above examples.

In addition, although the tenth insulating film INS10 and the eleventh insulating film INS11 are illustrated in the present disclosure, a twelfth insulating film located under the first electrode AND of the first sub-pixel SP1 may be added. In this case, the eleventh insulating film INS11 and the twelfth insulating film may be located under the first electrode AND of the second sub-pixel SP2, and the tenth insulating film INS10, the eleventh insulating film INS11, and the twelfth insulating film may be located under the first electrode AND of the third sub-pixel SP3.

Each of the tenth vias VA10 may penetrate the tenth insulating film INS10 and/or the eleventh insulating film INS11 in the second sub-pixel SP2 and the third sub-pixel SP3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be less than the thickness of the tenth via VA10 in the third sub-pixel SP3.

The first electrode AND of each of the light-emitting elements LE may be located on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

The pixel defining film PDL may be located on a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light-emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed of a silicon oxide (SiOx)-based inorganic film, but embodiments according to the present disclosure are not limited thereto. The first pixel defining film PDL1, the second pixel defining film PDL2, and the third pixel defining film PDL3 may each have a thickness of 500 Å (or about 500 Å).

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. The tenth insulating film INS10 may be partially recessed at each of the plurality of trenches TRC.

At least one trench TRC may be located between the neighboring sub-pixels SP1, SP2, and SP3. Although FIG. 7 illustrates that two trenches TRC are located between the neighboring sub-pixels SP1, SP2, and SP3, embodiments according to the present disclosure are not limited thereto.

The light-emitting stack IL may include a plurality of intermediate layers. FIG. 7 illustrates that the light-emitting stack IL has a three-tandem structure including a first stack layer IL1, a second stack layer IL2, and a third stack layer IL3, but embodiments according to the present disclosure are not limited thereto. For example, the light-emitting stack IL may have a two-tandem structure including two intermediate layers.

In the three-tandem structure, the light-emitting stack IL may have a tandem structure including a plurality of stack layers IL1, IL2, and IL3 that emit different lights. For example, the light-emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer 1 that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be located on the first electrodes AND and the pixel defining film PDL, and may be located on the bottom surface of each trench TRC. Due to the trench TRC, the first stack layer IL1 may be cut off between the neighboring sub-pixels SP1, SP2, and SP3. The second stack layer IL2 may be located on the first stack layer IL1. Due to the trench TRC, the second stack layer IL2 may be cut off between the neighboring sub-pixels SP1, SP2, and SP3. A cavity or an empty space may be located in the first stack layer IL1 and the second stack layer IL2. The third stack layer IL3 may be located on the second stack layer IL2. The third stack layer IL3 is not cut off by the trench TRC and may be arranged to cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EML between the neighboring sub-pixels SP1, SP2, and SP3. In addition, in the two-tandem structure, each of the trenches TRC may be a structure for cutting off the charge generation layer located between a lower intermediate layer and an upper intermediate layer, and the lower intermediate layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be located on the pixel defining film PDL.

The number of the stack layers IL1, IL2, and IL3 that emit different lights is not limited to that shown in FIG. 7. For example, the light-emitting stack IL may include two intermediate layers. In this case, one of the two intermediate layers may be the same (or substantially the same) as the first stack layer IL1, and the other may include a second hole transport layer, a second organic light-emitting layer, a third organic light-emitting layer, and a second electron transport layer. In this case, a charge generation layer for supplying electrons to one intermediate layer and supplying charges to the other intermediate layer may be located between the two intermediate layers.

In addition, FIG. 7 illustrates that the first to third stack layers IL1, IL2, and IL3 are all located in the first emission area EA1, the second emission area EA2, and the third emission area EA3, but embodiments according to the present disclosure are not limited thereto. For example, the first stack layer IL1 may be located in the first emission area EA1, and may be omitted from the second emission area EA2 and the third emission area EA3. Furthermore, the second stack layer IL2 may be located in the second emission area EA2 and may be omitted from the first emission area EA1 and the third emission area EA3. Further, the third stack layer IL3 may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be relatively improved in each of the first to third sub-pixels SP1, SP2, and SP3 due to a micro-cavity effect.

The encapsulation layer TFE may be located on the display element layer EML. The encapsulation layer TFE may include at least one inorganic film TFE1 and TFE2 to reduce or prevent contaminants such as oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be located on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed of titanium oxide (TiOx) or aluminum oxide (AlOx), but embodiments according to the present disclosure are not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the optical layer OPL. The organic film APL may be an organic film such as acrylic resin, epoxy resin, phenolic resin, polyamide resin, or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the organic film APL.

The first color filter CF1 may overlap the first emission area EA1 of the first sub-pixel SP1. The first color filter CF1 may transmit light of the first color, i.e., light of a blue wavelength band. The blue wavelength band may be in a range of 370 nanometers (nm) to 460 nm (or about 370 nm to about 460 nm). Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be in a range of 480 nm to 560 nm (or about 480 nm to about 560 nm). Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be in a range of 600 nm to 750 nm (or about 600 nm to about 750 nm). Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., a set or predetermined refractive index) such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a N/4 plate (quarter-wave plate), but embodiments according to the present disclosure are not limited thereto. However, when visibility degradation caused by reflection of external light is sufficiently overcome by the first to third color filters CF1, CF2, and CF3, the polarizing plate may be omitted.

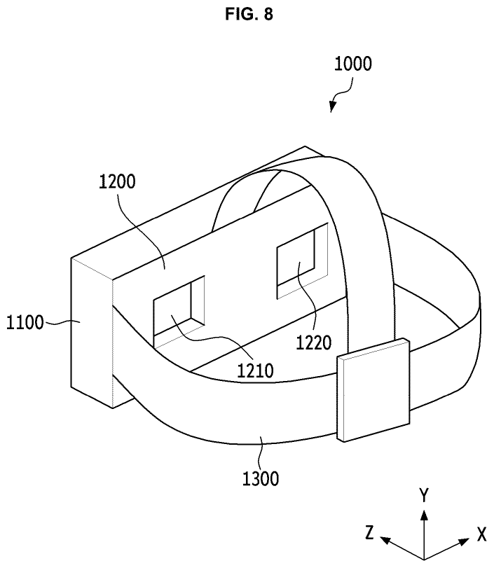

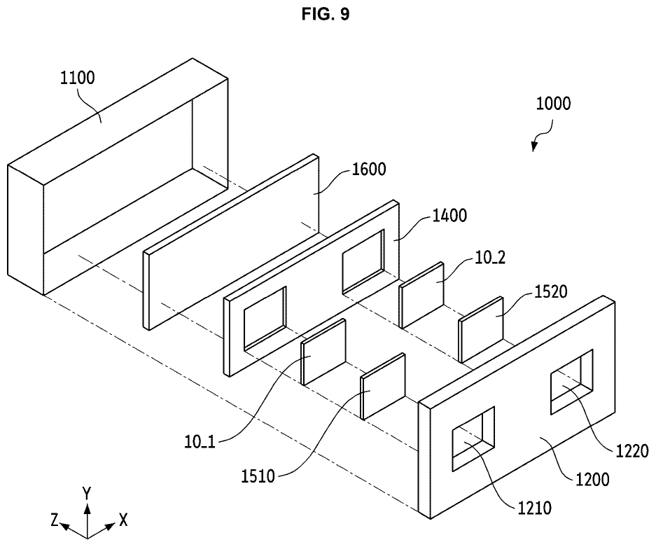

FIG. 8 is a perspective view illustrating a head mounted display according to some embodiments. FIG. 9 is an exploded perspective view illustrating an example of the head mounted display of FIG. 8.

Referring to FIGS. 8 and 9, a head mounted display 1000 according to some embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is the same (or substantially the same) as the display device 10 described in conjunction with FIGS. 1 and 2, description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are arranged separately, but embodiments according to the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

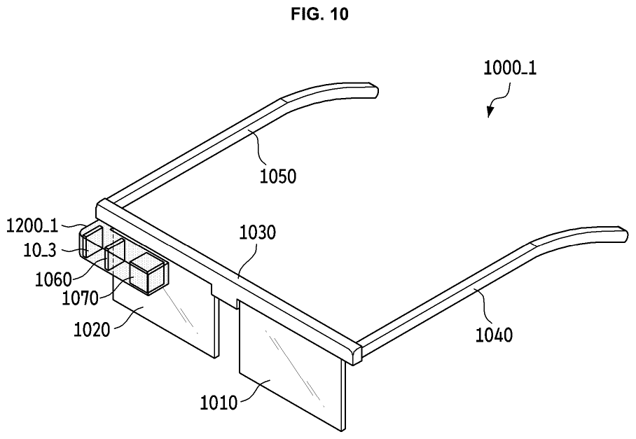

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 10, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view illustrating a head mounted display according to some embodiments.

Referring to FIG. 10, a head mounted display 1000_1 according to some embodiments may be an eyeglasses-type display device in which a display device housing 1200_1 is implemented in a lightweight and compact manner. The head mounted display 1000_1 according to some embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is located at the right end of the support frame 1030, but embodiments according to the present disclosure are not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

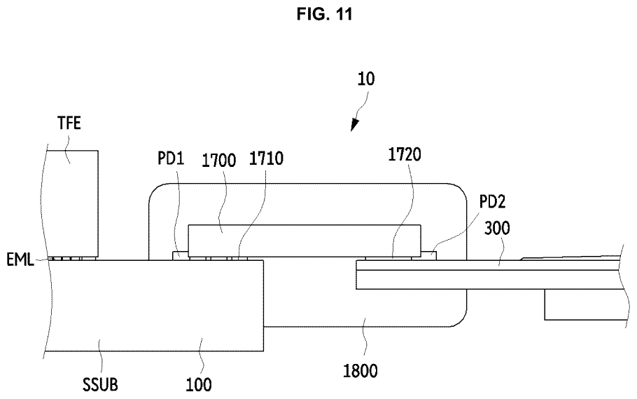

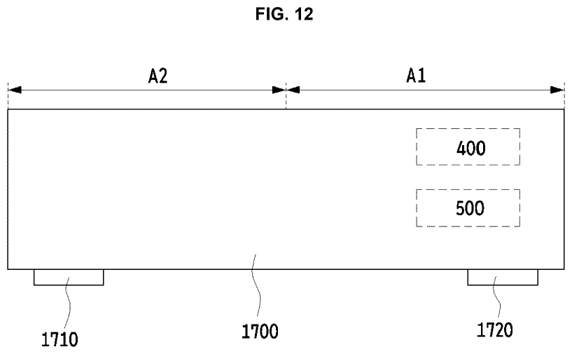

FIG. 11 is a cross-sectional view schematically illustrating an integrated circuit 1700 bonded to a pad portion of a display panel 100 according to some embodiments. FIG. 12 is a configuration diagram of the integrated circuit 1700 shown in FIG. 11.

Referring to FIGS. 11 and 12, a semiconductor substrate SSUB, a display element layer EML on the semiconductor substrate SSUB, and the like may be located inside the display panel 100.

The first pad portion PD1 is located at one side of the display panel 100. The first pad portion PD1 may include two or more rows of pads connected to wires, e.g., the data lines DL, of the display panel 100.

The first pad portion PD1 of the display panel 100 may be bonded to the integrated circuit (IC) 1700. The integrated circuit 1700 may not completely overlap the display panel 100, and a portion thereof may extend in an outward direction of the display panel 100. For example, the integrated circuit 1700 includes an overlapping region A2 (e.g., a first region) that overlaps the display panel 100 and a non-overlapping region A1 (e.g., a second region) that does not overlap the display panel 100.

The integrated circuit 1700 includes the timing controller 400 and the power supply circuit 500 (e.g., PMIC) for driving the display panel 100.

The integrated circuit 1700 includes a plurality of first bumps 1710 bonded to the first pad portion PD1 of the display panel 100 and a plurality of second bumps 1720 bonded to the second pad portion PD2 of the circuit board 300.

The timing controller 400 and the power supply circuit 500 are located inside the integrated circuit 1700, and are located adjacent to the plurality of second bumps 1720. The timing controller 400 and the power supply circuit 500 are components that generate significant heat. According to some embodiments of the present disclosure, the timing controller 400 and the power supply circuit 500, which generate significant heat, are located in the integrated circuit 1700, and they are located adjacent to the plurality of second bumps 1720 in the integrated circuit 1700, thereby reducing damage to the organic light-emitting layer from the heat generated by the driving circuit.

The non-overlapping region A1 of the integrated circuit 1700 may be bonded to the circuit board 300. The circuit board 300 is a flexible printed circuit board extending in the outward direction of the display panel 100, as the second pad portion PD2 is aligned in the forward direction with the plurality of second bumps 1720 of the integrated circuit 1700.

According to some embodiments, the display device 10 may include the integrated circuit 1700 and a molding member 1800 that covers a portion of the display panel 100 to which the integrated circuit 1700 is bonded. The molding member 1800 contains a material having heat dissipation characteristics.

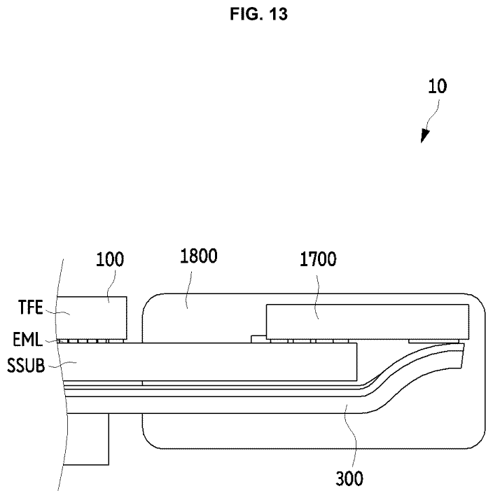

FIG. 13 is a cross-sectional view schematically illustrating a flexible printed circuit board bonded to the integrated circuit 1700 in the reverse direction according to some embodiments.

The embodiments of FIG. 13 differs from the embodiments of FIGS. 11 and 12 in that the circuit board 300 (i.e., the flexible printed circuit board) is bonded to the integrated circuit 1700 in the reverse direction. The circuit board 300 may be a flexible printed circuit board extending in the inward direction of the display panel 100, as the second pad portion PD2 is aligned in the reverse direction with the plurality of second bumps 1720 of the integrated circuit 1700.

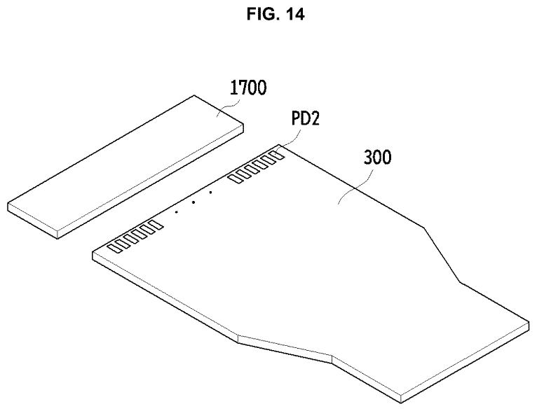

FIGS. 14 to 16 are conceptual diagrams illustrating a bonding process of the display device 10 according to some embodiments. Hereinafter, a bonding process of the display device 10 according to some embodiments will be described in more detail with reference to FIGS. 14 to 16.

Referring to FIG. 14, the integrated circuit 1700 and the circuit board 300 may be bonded to each other. The plurality of second bumps 1720 of the integrated circuit 1700 may be bonded to the second pad portion PD2 of the circuit board 300.

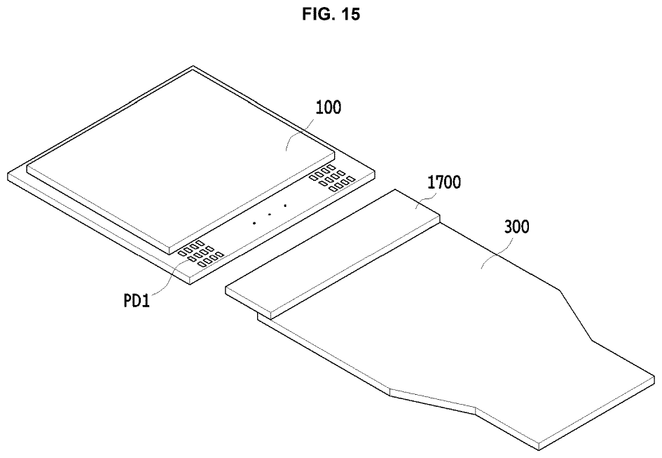

Subsequently, referring to FIG. 15, the plurality of first bumps 1710 of the integrated circuit 1700 may be bonded to the first pad portion PD1 of the display panel 100. Bonding of the integrated circuit 1700 may use ACF bonding, laser bonding, or ultrasonic bonding techniques.

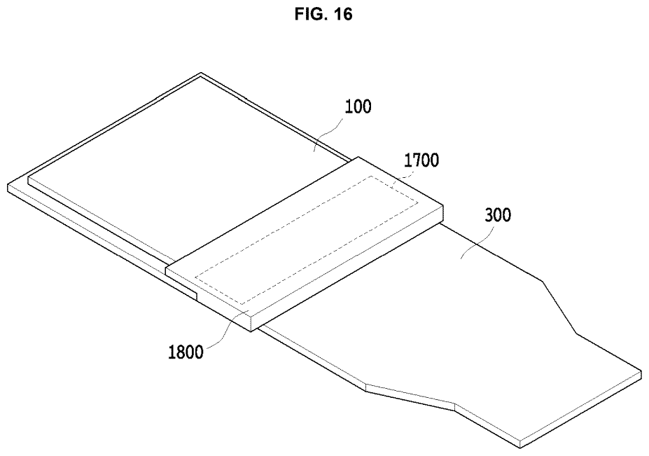

Subsequently, referring to FIG. 16, the molding member 1800 having heat dissipation characteristics may be used to cover the integrated circuit 1700 and a portion of the display panel 100 to which the integrated circuit 1700 is bonded. According to some embodiments of the present disclosure, the integrated circuit 1700 and a portion of the display panel 100 to which the integrated circuit 1700 is bonded may be covered with the molding member 1800, thereby reinforcing strength and relatively improving heat dissipation performance.

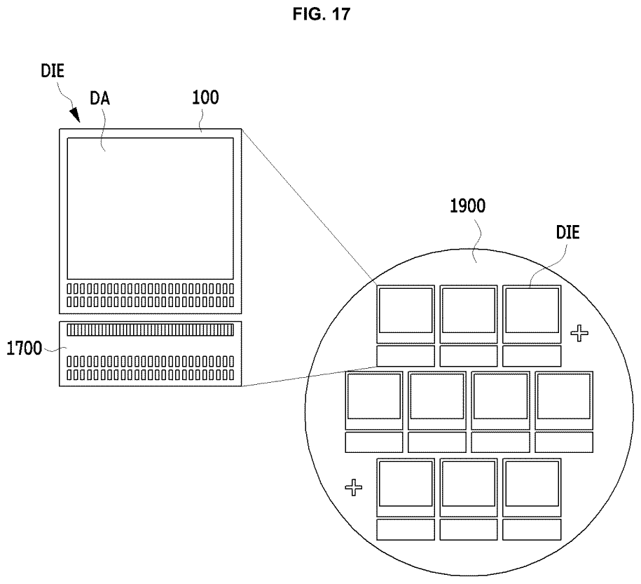

FIGS. 17 to 19 are conceptual diagrams for describing a method of manufacturing the display device 10 according to some embodiments. Hereinafter, a method of manufacturing the display device 10 according to some embodiments will be described with reference to FIGS. 17 to 19.

Referring to FIG. 17, a wafer substrate 1900 may be provided, and elements corresponding to the display area of the display panel 100 including the display element layer EML may be formed on the wafer substrate 1900. In addition, the integrated circuit 1700 may be formed adjacent to the elements corresponding to the display area of the display panel 100. Here, the integrated circuit 1700 is the integrated circuit 1700 described with reference to FIGS. 11 to 16, and may include the timing controller 400 and the power supply circuit 500 (e.g., PMIC).

On the wafer substrate 1900, the elements corresponding to the display area DA of the display panel 100, and the integrated circuit 1700 including the timing controller 400 and the power supply circuit 500 (e.g., PMIC) form a single die. For example, a single die may include the elements corresponding to the display area DA of the display panel 100, and the integrated circuit 1700 including the timing controller 400 and the power supply circuit 500 (e.g., PMIC), and a plurality of dies may be located on the wafer substrate 1900.

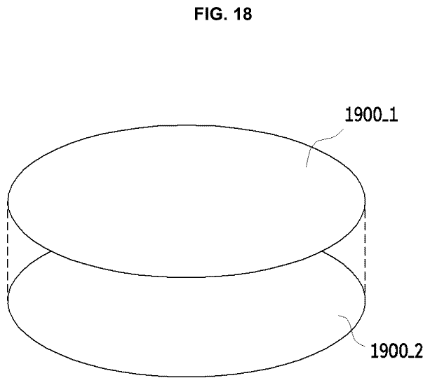

Referring to FIG. 18, a pair of wafer substrates 1900_1 and 1900_2 may be aligned to face each other. Each of the pair of wafer substrates 1900_1 and 1900_2 is configured such that the elements corresponding to the display area DA of the display panel 100, and the integrated circuit 1700 including the timing controller 400 and the power supply circuit 500 (e.g., PMIC) form a single die. For example, each of a first wafer substrate 1900_1 and a second wafer substrate 1900_2 shown in FIG. 18 may be the wafer substrate 1900 described with reference to FIG. 17.

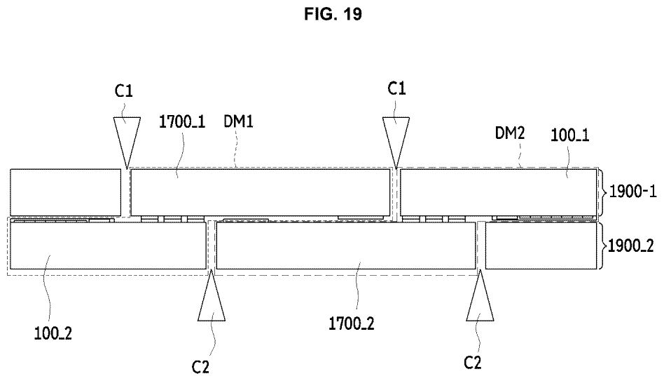

Referring to FIG. 19, the first wafer substrate 1900_1 and the second wafer substrate 1900_2 may be bonded to each other, and a cell cutting process may be performed.

For example, when the first wafer substrate 1900_1 is aligned on the second wafer substrate 1900_2, an integrated circuit 1700_1 of the first wafer substrate 1900_1 and a display panel 100_2 of the second wafer substrate 1900_2 may form a first display module DM1. In addition, a display panel 100_1 of the first wafer substrate 1900_1 and an integrated circuit 1700_2 of the second wafer substrate 1900_2 may form a second display module DM2.

In FIG. 19, C1 represents a cutting region for cutting each cell of the first wafer substrate 1900_1.

In FIG. 19, C2 represents a cutting region for cutting each cell of the second wafer substrate 1900_2.

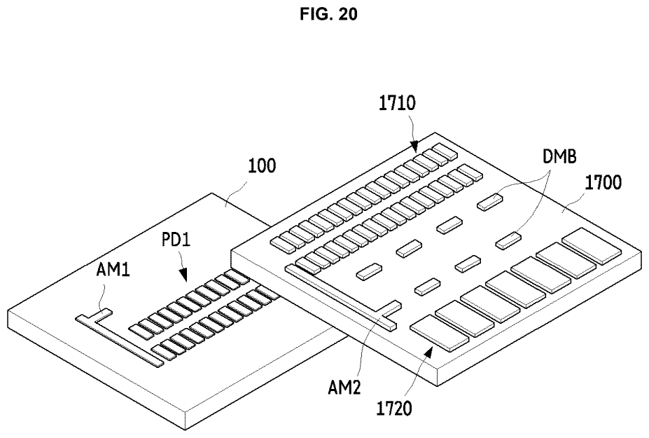

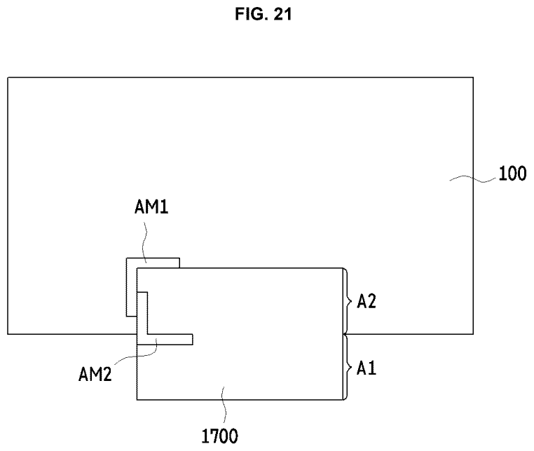

FIGS. 20 and 21 are diagrams illustrating a first alignment mark AM1 of the display panel 100 and a second alignment mark AM2 of the integrated circuit 1700 according to some embodiments. For example, FIG. 20 may be a perspective view illustrating a portion of the display panel 100 including the first alignment mark AM1 and a portion of the integrated circuit 1700 including the second alignment mark AM2. For example, FIG. 21 may be a plan view illustrating a portion of the display panel 100 including the first alignment mark AM1 and a portion of the integrated circuit 1700 including the second alignment mark AM2.

Referring to FIGS. 20 and 21, the first pad portion PD1 of the display panel 100 may include the first alignment mark AM1 for identifying the boundary of the corner of the integrated circuit 1700.

The first alignment mark AM1 may be located outside the first pad portion PD1.

The first alignment mark AM1 has a bent shape that does not overlap the integrated circuit 1700. The first alignment mark AM1 serves as an indicator for identifying the corner of the integrated circuit 1700 when the integrated circuit 1700 is bonded to the first pad portion PD1 of the display panel 100.

The integrated circuit 1700 includes the second alignment mark AM2 for identifying the boundary of the non-overlapping region A1, and the second alignment mark AM2 has a bent shape at the boundary of the non-overlapping region A1. The second alignment mark AM2 serves as an indicator for distinguishing the boundary between the overlapping region A2 and the non-overlapping region A1 of the integrated circuit 1700 when the integrated circuit 1700 is bonded to the first pad portion PD1 of the display panel 100.

According to some embodiments, the integrated circuit 1700 includes at least one step compensation bump DMB located between the plurality of first bumps 1710 and the plurality of second bumps 1720. The step compensation bump DMB serves to maintain a flat state of the integrated circuit 1700 when the integrated circuit 1700 is bonded to the first pad portion PD1 of the display panel 100.

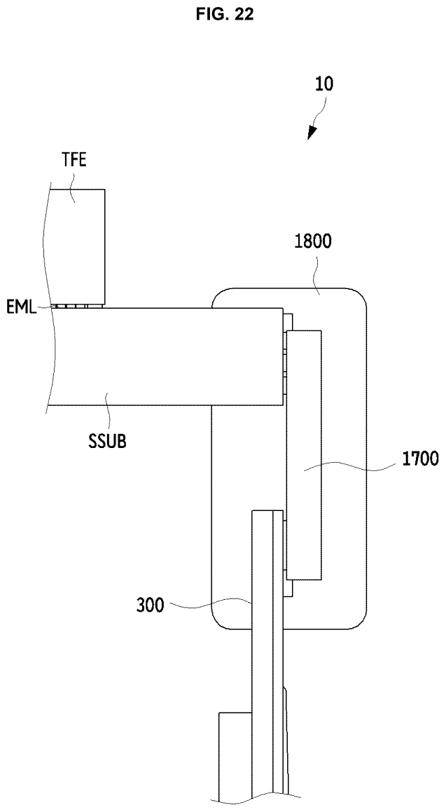

FIG. 22 is a cross-sectional view illustrating the integrated circuit 1700 bonded to the side surface of the display panel 100 according to some embodiments.

The embodiments of FIG. 22 differs from the embodiments of FIGS. 11 and 12 in that the integrated circuit 1700 is bonded to the side surface of the display panel 100.

According to the embodiments of FIG. 22, the first pad portion PD1 of the display panel 100 may be located on the side surface of the display panel 100, and the integrated circuit 1700 may be bonded to the first pad portion PD1 at the side surface of the display panel 100. The integrated circuit 1700 may be arranged such that only a portion thereof covers the side surface of the display panel 100, similarly to the embodiments of FIGS. 11 and 12.

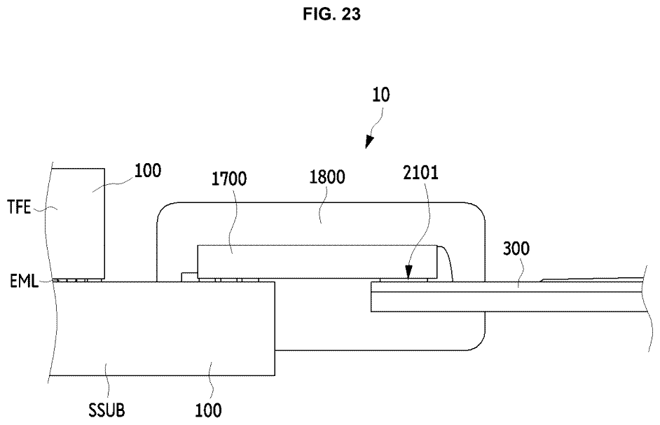

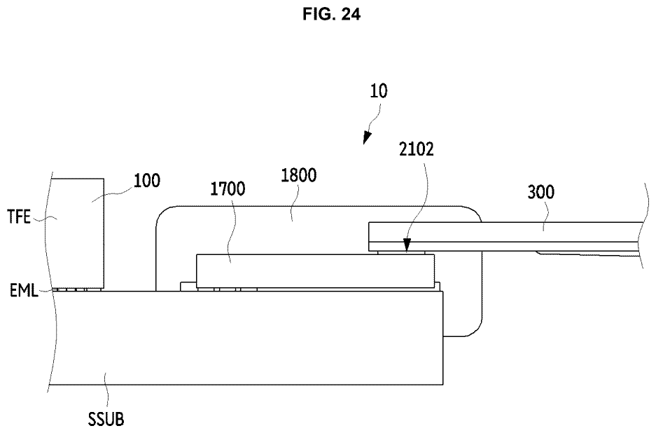

FIGS. 23 and 24 are cross-sectional views illustrating an example in which the circuit board 300 is a chip on film (COF) according to some embodiments.

The embodiments of FIGS. 23 and 24 differs from the embodiments of FIGS. 11 and 12 in that the circuit board 300 is a chip on film (COF).

Referring to FIG. 23, the circuit board 300 is a chip on film (COF), and as the second pad portion PD2 is aligned in the forward direction with the plurality of second bumps 1720 (see FIG. 20) of the integrated circuit 1700, the circuit board 300 may extend in the outward direction of the display panel 100.

Referring to FIG. 24, the circuit board 300 is a chip on film (COF), and the second pad portion PD2 may be bonded to the plurality of second bumps 1720 located on the top surface of the integrated circuit 1700. For example, in the embodiments of FIG. 23, as indicated by arrow 2101, the chip on film (COF), which is the circuit board 300, is bonded to the plurality of second bumps 1720 (see FIG. 20) located on the bottom surface of the integrated circuit 1700. In the embodiments of FIG. 24, as indicated by arrow 2102, the chip on film (COF), which is the circuit board 300, is bonded to the plurality of second bumps 1720 (see FIG. 20) located on the top surface of the integrated circuit 1700.

In concluding the detailed description, those skilled in the art will appreciate that many variations and modifications can be made to the disclosed embodiments without departing from the spirit and scope of embodiments according to the present disclosure. Therefore, the disclosed embodiments of the invention are used in a generic and descriptive sense only and not for purposes of limitation.

What is claimed is:

1. A display device comprising:
a display panel on which a display element layer comprising a light-emitting element is located;
an integrated circuit (IC) bonded to a first pad portion of the display panel, and comprising a non-overlapping region that does not overlap the display panel;
a circuit board bonded to the non-overlapping region of the integrated circuit; and
a molding member covering the integrated circuit and a portion of the display panel to which the integrated circuit is bonded.

2. The display device of claim 1, wherein the integrated circuit comprises:
a plurality of first bumps bonded to the first pad portion of the display panel; and
a plurality of second bumps bonded to a second pad portion of the circuit board.

3. The display device of claim 2, wherein the integrated circuit comprises a timing controller and a power supply circuit configured to drive the display panel.

4. The display device of claim 3, wherein the timing controller and the power supply circuit are inside the integrated circuit, and are adjacent to the plurality of second bumps.

5. The display device of claim 1, wherein the molding member contains a heat dissipation material.

6. The display device of claim 2, wherein the circuit board is a flexible printed circuit board extending in an outward direction of the display panel, as the second pad portion is aligned in a forward direction with the plurality of second bumps of the integrated circuit.

7. The display device of claim 2, wherein the circuit board is a flexible printed circuit board extending in an inward direction of the display panel, as the second pad portion is aligned in a reverse direction with the plurality of second bumps of the integrated circuit.

8. The display device of claim 1, wherein the circuit board is a chip on film (COF).

9. The display device of claim 2, wherein the first pad portion of the display panel comprises a first alignment mark for identifying a boundary of a corner of the integrated circuit, and
the first alignment mark has a bent shape that does not overlap the integrated circuit.

10. The display device of claim 2, wherein the integrated circuit comprises a second alignment mark for identifying a boundary of the non-overlapping region, and
the second alignment mark has a bent shape at the boundary of the non-overlapping region.

11. The display device of claim 2, wherein the integrated circuit comprises at least one step compensation bump between the plurality of first bumps and the plurality of second bumps.

12. The display device of claim 1, wherein the display panel is an organic light-emitting diode-on-silicon (OLEDoS) in which the light-emitting element is on a silicon substrate.

13. A mobile electronic device comprising:
a display panel on which a display element layer comprising a light-emitting element is located;
an integrated circuit (IC) bonded to a first pad portion located on a side surface of the display panel, and comprising a non-overlapping region that does not overlap the display panel;
a circuit board bonded to the non-overlapping region of the integrated circuit; and
a molding member covering the integrated circuit and a portion of the display panel to which the integrated circuit is bonded.

14. The mobile electronic device of claim 13, wherein the integrated circuit comprises:
a plurality of first bumps bonded to the first pad portion of the display panel; and
a plurality of second bumps bonded to a second pad portion of the circuit board.

15. The mobile electronic device of claim 14, wherein the integrated circuit comprises a timing controller and a power supply circuit configured to drive the display panel, and wherein the timing controller and the power supply circuit are inside the integrated circuit, and are adjacent to the plurality of second bumps.

16. The mobile electronic device of claim 13, wherein the molding member contains a heat dissipation material.

17. The mobile electronic device of claim 13, wherein the circuit board is a flexible printed circuit board extending in an outward direction of the display panel, as the second pad portion is aligned in a forward direction with the plurality of second bumps of the integrated circuit.

18. The mobile electronic device of claim 14, wherein the first pad portion of the display panel comprises a first alignment mark for identifying a boundary of a corner of the integrated circuit, and
the first alignment mark has a bent shape that does not overlap the integrated circuit.

19. The mobile electronic device of claim 14, wherein the integrated circuit comprises a second alignment mark for identifying a boundary of the non-overlapping region, and
the second alignment mark has a bent shape at the boundary of the non-overlapping region.

20. The mobile electronic device of claim 13, wherein the mobile electronic device is one of a mobile phone, a smartphone, a tablet personal computer, a mobile communication terminal, an electronic organizer, an electronic book, a portable multimedia player (PMP), a navigation system, an ultra mobile PC (UMPC), a television, a laptop, a monitor, a billboard, an Internet-of-Things (IoT) device, a smart watch, a watch phone, or a head mounted display (HMD).
